(19) United States
(12) Patent Application Publication
(10) Pub. No.: US 2019/0312073 A1
(43) Pub. Date: Oct. 10, 2019

(54) IMAGE SENSOR

(71) Applicant: HUAIAN IMAGING DEVICE MANUFACTURER CORPORATION, Huaian (CN)

(72) Inventors: Zengzhi HUANG, HUAIAN (CN); Haifeng LONG, HUAIAN (CN); Tianhui LI, HUAIAN (CN); Xiaolu HUANG, HUAIAN (CN)

(73) Assignee: HUAIAN IMAGING DEVICE MANUFACTURER CORPORATION, HUAIAN (CN)

(21) Appl. No.: 16/374,485

(22) Filed: Apr. 3, 2019

(30) Foreign Application Priority Data
Apr. 4, 2018 (CN) 201810293563.2

(51) Int. Cl. H01L 27/146

(52) U.S. Cl. CPC H01L 27/14627; H01L 27/14621; H01L 27/14645; H01L 27/14685; H01L 27/1463; H01L 27/1462

(57) ABSTRACT

The present disclosure relates to an image sensor comprising: a photodiode; a color filter located above the photodiode; and a converging lens located between the photodiode and the color filter, wherein the converging lens is configured to converge light onto the photodiode. The image sensor can make the configuration of the image sensor more compact while preventing crosstalk of light between pixel cells.

### CROSS-REFERENCE TO RELATED APPLICATIONS

This application claims priority to Chinese Patent Application No. 201810293563.2, filed on Apr. 4, 2018, which is hereby incorporated by reference in its entirety.

### TECHNICAL FIELD

The present disclosure relates generally to the field of semiconductor technology, and more particularly, to an image sensor.

### BACKGROUND

An image sensor typically includes a plurality of pixel cells arranged in an array, each of the pixel cells may include a photodiode that is capable of converting incident light into electrical charges. Each of the pixel cells may further include a color filter and a microlens for the pixel cell located above the photodiode. It should be noted that the orientation terms used herein are referenced to the direction that the surface of the image sensor that is used to receive light is up, i.e., the direction shown in the drawings.

### SUMMARY

One of aims of the present disclosure is to provide a novel image sensor.

One aspect of this disclosure is to provide an image sensor. The image sensor may comprise: a photodiode; a color filter located above the photodiode; and a converging lens located between the photodiode and the color filter, wherein the converging lens is configured to converge light onto the photodiode.

Further features of the present disclosure and advantages thereof will become apparent from the following detailed description of exemplary embodiments with reference to the attached drawings.

### BRIEF DESCRIPTION OF THE DRAWINGS

The accompanying drawings, which constitute a part of the specification, illustrate embodiments of the present disclosure and, together with the description, serve to explain the principles of the present disclosure.

The present disclosure will be better understood according the following detailed description with reference of the accompanying drawings.

FIG. 1 schematically illustrates a configuration of an image sensor according to an exemplary embodiment of this disclosure.

FIG. 2 schematically illustrates a configuration of an image sensor according to a further exemplary embodiment of this disclosure.

FIGS. 3 to 11 schematically illustrate respectively a method for manufacturing the image sensor according to exemplary embodiments of this disclosure, in fragmentary cross sections of the image sensor at one or more steps.

FIGS. 12 to 20 schematically illustrate respectively a method for manufacturing the image sensor according to exemplary embodiments of this disclosure, in fragmentary cross sections of the image sensor at one or more steps.

Note that, in the embodiments described below, in some cases the same portions or portions having similar functions are denoted by the same reference numerals in different drawings, and description of such portions is not repeated. In some cases, similar reference numerals and letters are used to refer to similar items, and thus once an item is defined in one figure, it need not be further discussed for following figures.

In order to facilitate understanding, the position, the size, the range, or the like of each structure illustrated in the drawings and the like are not accurately represented in some cases. Thus, the disclosure is not necessarily limited to the position, size, range, or the like as disclosed in the drawings and the like.

### DETAILED DESCRIPTION

Various exemplary embodiments of the present disclosure will be described in details with reference to the accompanying drawings in the following. It should be noted that the relative arrangement of the components and steps, the numerical expressions, and numerical values set forth in these embodiments do not limit the scope of the present invention unless it is specifically stated otherwise.

The following description of at least one exemplary embodiment is merely illustrative in nature and is in no way intended to limit this disclosure, its application, or uses.

Techniques, methods and apparatus as known by one of ordinary skill in the relevant art may not be discussed in detail, but are intended to be regarded as a part of the specification where appropriate.

In all of the examples as illustrated and discussed herein, any specific values should be interpreted to be illustrative only and non-limiting. Thus, other examples of the exemplary embodiments could have different values.

In the present disclosure, a reference to “one embodiment” or “an embodiment” means that the features, structures, or characteristics described in connection with the embodiments are included in at least one embodiment, at least some embodiments of the present disclosure. Thus, appearances of the phrases “in one embodiment” and “the” Furthermore, the features, structures, or characteristics may be combined in any suitable combination and/or sub-combination in one or more embodiments.

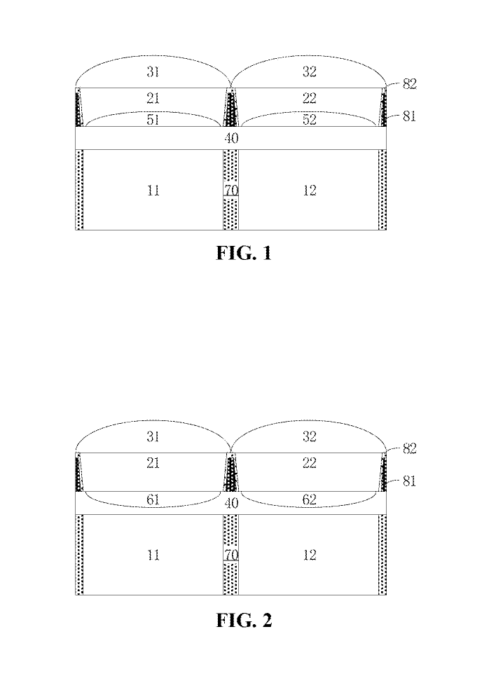

Image sensors according to embodiments of the present disclosure are shown in FIGS. 1 and 2. The image sensor may comprise photodiodes 11, 12; color filters 21, 22 located above the photodiodes 11, 12; and converging lenses 51, 52 or 61, 62 that locate between the photodiodes 11, 12 and the color filters 21, 22, respectively. The converging lenses 51, 52 or 61, 62 may converge incident light onto the photodiodes 11, 12. The light from an upper side of the image sensor passes through the microlenses 31, 32 so as to be converged for the first time, and then passes through the converging lenses 51, 52 so as to be converged for the first time, so that the focus of the light is closer to the upper side of the image sensor in the vertical direction, for example, closer to the color filters 21, 22. Thus, the PN junctions of the photodiodes 11, 12 may be arranged closer to the upper side of the image sensor so as to shorten the optical path of the light, so that the image sensor may be more compact in the vertical direction. The image sensor may be used for imaging close-range objects in addition to usual imaging purposes, for example, in the fields of micro-photography and near-field imaging.

Further, the converging lenses 51, 52 may make the light entering the photodiodes 11, 12 to be more concentrated, so that the area of the photodiodes 11, 12 may be smaller. Thus, the size of the pixel cell may be reduced while the number of the pixel cells may be increased, which is advantageous for the resolution of the image sensor. Moreover, the converging lenses 51, 52 may make the light entering the photodiodes 11, 12 to be more concentrated, so that the crosstalk of light between neighboring pixel cells may be reduced.

In some embodiments, the image sensor may further include an anti-reflection layer 40 located between the photodiodes 11, 12 and the color filters 21, 22. The converging lenses 51, 52 or 61, 62 are located between the anti-reflection layer 40 and the color filters 21, 22.

In some embodiments, as shown in FIG. 1, the lower surfaces of the converging lenses 51, 52 are flat and the upper surfaces are curved, and the upper surfaces of the converging lenses 51, 52 are completely covered by the color filters 21, 22. Preferably, the upper surfaces of the converging lenses 51, 52 are in direct contact with the color filters 21, 22. Thus, the converging lenses 51, 52 are formed in the layer in which the color filters 21, 22 are located, that is, the converging lens is formed to be in a common layer with the color filters 21, 22, respectively, with occupying a portion of the space of the color filters in the prior art, so that the converging lenses 51, 52 are added to the image sensor without increasing the thickness of the image sensor.

In some embodiments, in order to ensure the convergence effect of the converging lenses 51, 52 on the incident light, the refractive index of the material forming the converging lenses 51, 52 is greater than the refractive index of the material forming the color filters 21, 22. As shown in FIG. 1, the converging lenses 51, 52 are located in the layer in which the color filters 21, 22 are located, and since the converging lenses 51, 52 are convex lenses, at least part of the color filters 21, 22 are formed as concave lenses (diverging lenses). Therefore, in the case where the refractive index of the material forming the converging lenses 51, 52 is greater than the refractive index of the material forming the color filters 21, 22, the convergence of the light generated by the converging lenses 51, 52 is greater than the divergence of the light generated by the diverging lens that are formed by the color filters 21, 22 according to the principle of equal-path imaging. Thus, the light may be converged toward the photodiodes 11, 12 after passing through the color filters 21, 22 and the converging lenses 51, 52.

In some embodiments, as shown in FIG. 2, the upper surfaces of the converging lenses 61, 62 are planar and the lower surfaces are curved, and the lower surfaces of the converging lenses 61, 62 are completely covered by the anti-reflection layer 40. Preferably, the lower surfaces of the converging lenses 61, 62 are in direct contact with the anti-reflection layer 40. Thus, the converging lenses 61, 62 are formed in the layer in which the anti-reflection layer 40 is located, that is, the converging lens is formed to be in a common layer with the anti-reflection layer 40 with occupying a portion of the space of the anti-reflection layer in the prior art, so that the converging lenses 61, 62 are added to the image sensor without increasing the thickness of the image sensor.

In some embodiments, in order to ensure the convergence effect of the converging lenses 61, 62 on the incident light, the refractive index of the material forming the converging lenses 61, 62 is greater than the refractive index of the material forming the anti-reflection layer 40. As shown in FIG. 2, the converging lenses 61, 62 are located in the layer in which the anti-reflection layer 40 is located, and since the converging lenses 61, 62 are convex lenses, at least part of the anti-reflection layer 40 are formed as concave lenses (diverging lenses). Therefore, in the case where the refractive index of the material forming the converging lenses 61, 62 is greater than the refractive index of the material forming the anti-reflection layer 40, the convergence of the light generated by the converging lenses 61, 62 is greater than the divergence of the light generated by the diverging lens that are formed by the anti-reflection layer 40 according to the principle of equal-path imaging. Thus, the light may be converged toward the photodiodes 11, 12 after passing through the converging lenses 61, 62 and the anti-reflection layer 40.

In some embodiments, as shown in FIGS. 1 and 2, the image sensor may further include an optical isolation structure (comprising a body portion 81 and a cover portion 82). The optical isolation structure may be located around the color filters 21, 22 and used for optical isolation between pixel cells of the image sensor so as to reduce crosstalk of light between pixel cells. The body portion 81 may be formed of a metal material such as gold, silver, copper, aluminum, or the like. The cover portion 82 may be formed of a dielectric material such as silicon oxide, silicon nitride, or the like.

In accordance with another aspect of the present disclosure, a method for manufacturing an image sensor is further provided. The method includes: forming converging lenses 51, 52 or 61, 62 above a semiconductor substrate which is used for forming photodiodes 11, 12 therein, wherein the converging lenses 51, 52 or 61, 62 are configured to converge light onto the photodiodes 11, 12, respectively; and forming the color filters 21, 22 above the converging lenses 51, 52 or 61, 62, respectively. In some embodiments, forming the converging lenses 51, 52 or 61, 62 above the semiconductor substrate includes: forming an anti-reflection layer 40 above the semiconductor substrate and forming converging lenses 51, 52 or 61, 62 above the anti-reflection layer 40.

In some embodiments, the converging lenses 51, 52 each have a first shape whose lower surface is flat and upper surface is curved, and the upper surfaces of the converging lenses 51, 52 are completely covered by the color filters 21, 22. Preferably, the upper surfaces of the converging lenses 51, 52 are in direct contact with the color filters 21, 22. In an example, the converging lenses 51, 52 may be formed by: forming a lens material layer 50 above the anti-reflection layer 40; forming a photoresist layer above the lens material layer 50; forming the photoresist layer into the first shape (e.g., photoresist portions 91, 92 each having the first shape) at least by means of a reflow process and/or a nano-imprint lithography; and etching the lens material layer 50 under the masking of the photoresist layer that is formed into the first shape such that the lens material layer 50 is formed as the converging lens 51, 52. Here, the refractive index of the material forming the lens material layer 50 is greater than the refractive index of the material forming the color filters 21, 22.

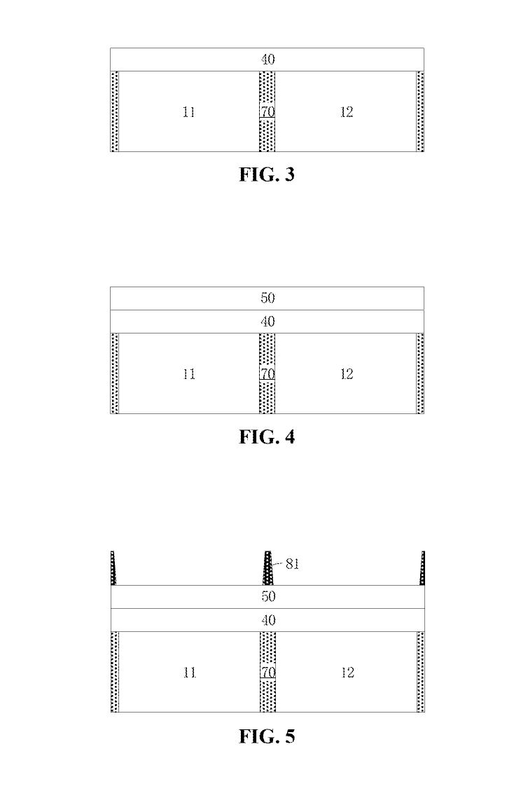

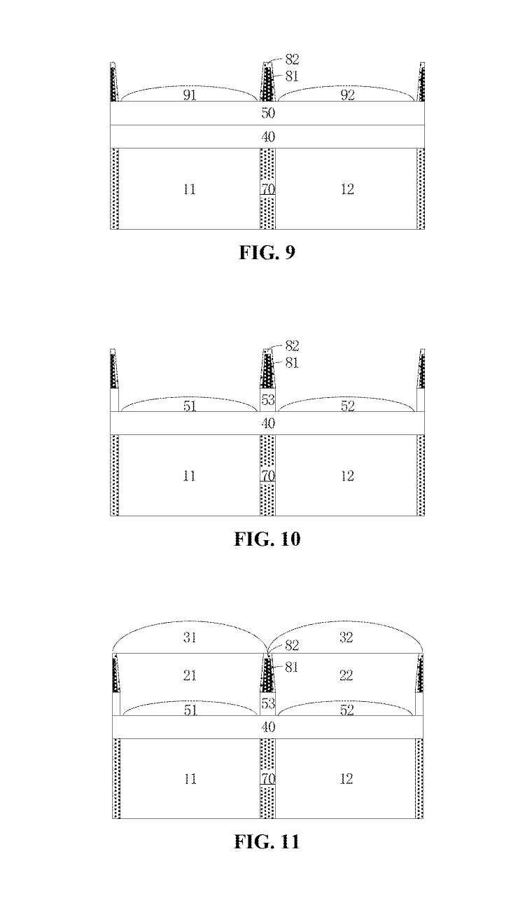

A method for manufacturing an image sensor will be described in detail below with reference to FIGS. 3 through 11.

As shown in FIG. 3, photodiodes 11 12, and an electrical isolation structures 70 between the photodiodes 11, 12 are formed in a semiconductor substrate, and an anti-reflection layer 40 is formed above the semiconductor substrate. As shown in FIG. 4, a lens material layer 50 is formed above the anti-reflection layer 40. The material forming the lens material layer 50 may be an organic optical material, silicon nitride, a pure oxide (for example, HfO₂ or the like), or a doped oxide or the like.

As shown in FIG. 5, a body portion 81 of an optical isolation structure for optical isolation between pixel cells is formed above the lens material layer 50. The body portion 81 is located around the color filters 21, 22 to be formed, that is, above the peripheral and/or surrounding regions of the photodiodes 11, 12. The body portion 81 is formed of a material that is opaque to light, for example, may be formed of a metal material such as gold, silver, copper, aluminum, etc. The shape of the cross section of the body portion 81 along the direction perpendicular to the main surface of the image sensor may be a rectangle, a trapezoid, a triangle, or the like. The size of the body portion 81 may be design as needed.

There are multiple approaches to form the body portion 81. In an example, a body layer (not shown) may be formed above the lens material layer 50 with an opaque material, and then portions of the body layer that are located directly above the photodiodes 11, 12 are removed, leaving portions of the body layer that are located directly above the peripheral and/or surrounding regions of the photodiodes 11, 12. These leaving portions are formed as the body portion 81. In a further example, a photoresist layer (not shown) may be formed above the lens material layer 50, and the photoresist layer has a sufficient thickness. Then the photoresist layer is exposed and developed so as to remove portions of the photoresist layer that are located directly above the peripheral and/or surrounding regions of the photodiodes 11, 12 and leave portions of the photoresist layer that are located directly above the photodiodes 11, 12. Then an opaque material is deposited (for example, by chemical vapor deposition (CVD), atomic layer deposition (ALD), or the like) above the photoresist layer that has been exposed and developed, such that the opaque material fills the portions of the photoresist layer that are removed by exposure and development processes. The photoresist layer that is located above the lens material layer 50 is completely stripped so that the opaque material that is deposited above the photoresist layer is also stripped together with the photoresist layer, while the opaque material that is filled the portions of the photoresist layer that are removed by exposure and development processes is retained. In a further example, the body portion 81 may be formed by an approach as shown in FIGS. 16 to 19, and a detailed description is described later.

As shown in FIG. 6, a dielectric material layer 80 that completely covers the body portion 81 is formed above the lens material layer 50 after the body portion 81 is formed. The dielectric material layer 80 may be formed of a dielectric material such as silicon oxide or silicon nitride by chemical vapor deposition, physical vapor deposition (PVD) or the like. The height of the dielectric material layer 80 is greater than the height of the body portion 81 to form the cover portion 82 in a subsequent step.

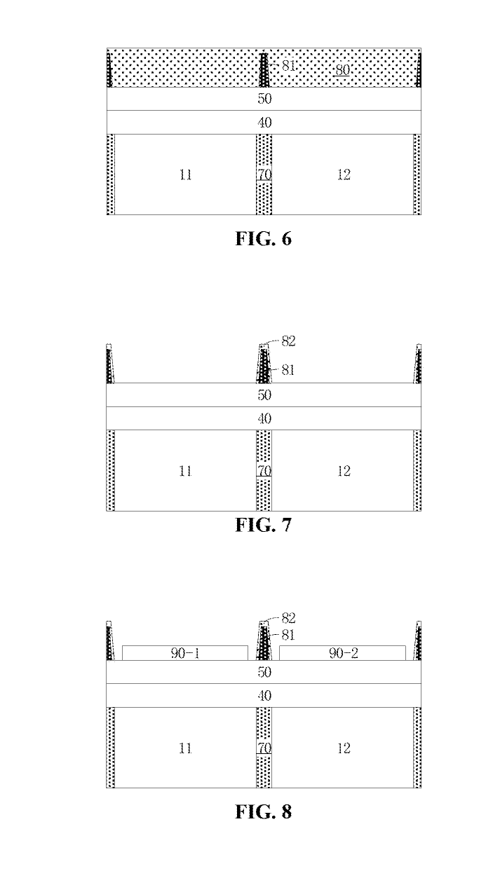

As shown in FIG. 7, portions of the dielectric material layer 80 that do not cover the body portion 81, such as the portions that are directly above the photodiodes 11, 12, are removed, with leaving the cover portion 82 that covers the body portion 81 so that openings are formed directly above the photodiodes 11, 12. This step may be performed by photolithography and etching processes. For example, a layer of photoresist may be applied above a dielectric material layer 80, and then the photoresist is subjected to exposure development processes to retain the photoresist directly above the body portion 81 and remove others. The width of the retained photoresist is greater than the width of the body portion 81. Then the dielectric material layer 80 is etched so as to remove portions of the dielectric material layer 80 that do not cover the body portion 81.

A layer of photoresist is applied above the lens material layer 50 on which the body portion 81 and the cover portion 82 are formed, and then the photoresist is subjected to exposure and development processes so as to leave only portions of the photoresist that is directly above the photodiodes 11, 12 (i.e., located between adjacent optical isolation structures) which are formed as photoresist portions 90-1, 90-2 as shown in FIG. 8. In order to ensure that the photoresist portions 90-1, 90-2 may be formed each into a desired shape in the subsequent steps, the photoresist portions 90-1, 90-2 that are formed by means of the exposure and development processes may have appropriate distances from the optical isolation structures.

The photoresist portions 90-1, 90-2 are subjected to a heat treatment to reflow the photoresist, so that the upper surfaces of the photoresist portions 90-1, 90-2 are formed into upward convex curved surfaces, that is, shape adjustment portions 91, 92 as shown in FIG. 10. The shapes of the shape adjustment portions 91, 92 match the shapes of the converging lenses 51, 52 to be formed. It will be appreciated that the shape adjustment portions 91, 92 may be formed by other approaches, for example, by nano-imprint lithography.

The lens material layer 50 is etched under the masking of the shape adjustment portions 91, 92, so that the shapes of the shape adjustment portions 91, 92 are transferred to the lens material layer 50. Thus, the lens material layer 50 is formed into the converging lenses 51, 52 as shown in FIG. 10. Since the etching process of this step is also performed under the masking of the optical isolation structures above the lens material layer 50, a portion of the lens material layer 50 under the optical isolation structures are not etched, so as to be formed into the remaining portion 53.

As shown in FIG. 11, color filters 21, 22 are formed above the converging lenses 51, 52 such that the color filters 21, 22 are filled between adjacent optical isolation structures, and then microlenses 31, 32 are formed above the color filters 21, 22, respectively.

In some embodiments, the converging lenses 61, 62 each have a second shape whose upper surface is flat and lower surface is curved, and the lower surfaces of the converging lenses 61, 62 are completely covered by the anti-reflection layer 40. Preferably, the lower surfaces of the converging lenses 61, 62 are in direct contact with the anti-reflection layer 40. In an example, the converging lenses 61, 62 may be formed by: forming a photoresist layer 90 above the anti-reflection layer 40; forming the photoresist layer 90 into the second shape (e.g., forming pits 93, 94 in the photoresist layer 90 as shown FIG. 13); etching the anti-reflection layer 40 under the masking of the photoresist layer 90 that is formed into the second shape such that pits 41, 42 each matching the second shape are formed in the anti-reflection layer 40; and filling a lens material into the pits 41, 42 to form the converging lenses 61, 62, wherein the refractive index of the lens material is greater than the refractive index of the material forming the anti-reflection layer 40.

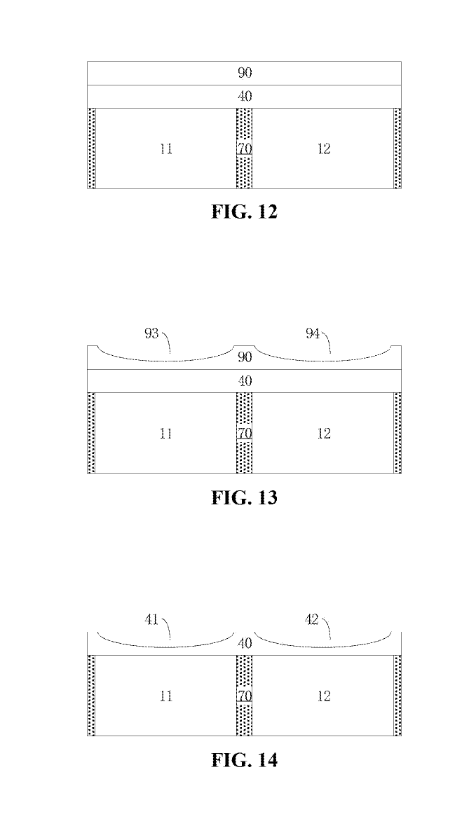

A method for manufacturing an image sensor will be described in detail below with reference to FIGS. 12 through 20.

As shown in FIG. 12, photodiodes 11, 12 and an electrical isolation structure 70 between the photodiodes 11, 12 are formed in a semiconductor substrate, and an anti-reflection layer 40 is formed above the semiconductor substrate. Then a photoresist layer 90 is formed above the anti-reflection layer 40.

As shown in FIG. 13, pits 93, 94 which match the shapes of the respective converging lenses 61, 62 to be formed are formed in the photoresist layer 90. For example, an etch process or a nano-imprint lithography may be used to form the pits 93, 94.

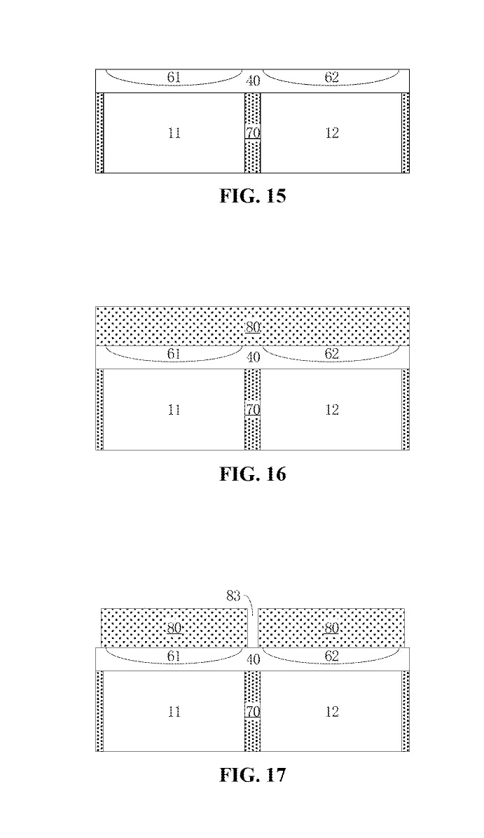

Under the masking of the photoresist layer 90 having the pits 93, 94, the anti-reflection layer 40 is etched such that the shapes of the pits 93, 94 that is formed in the photoresist layer 90 are transferred into the anti-reflection layer 40, thereby pits 41, 42 that match the shapes of the converging lenses 61, 62 to be formed are formed in the anti-reflection layer 40, as shown in FIG. 14. A lens material is filled in the pits 41, 42 formed in the anti-reflection layer 40 to form converging lenses 61, 62 as shown in FIG. 15. The lens material may be an organic optical material, silicon nitride, a pure oxide (e.g., HfO₂ or the like), or a doped oxide or the like.

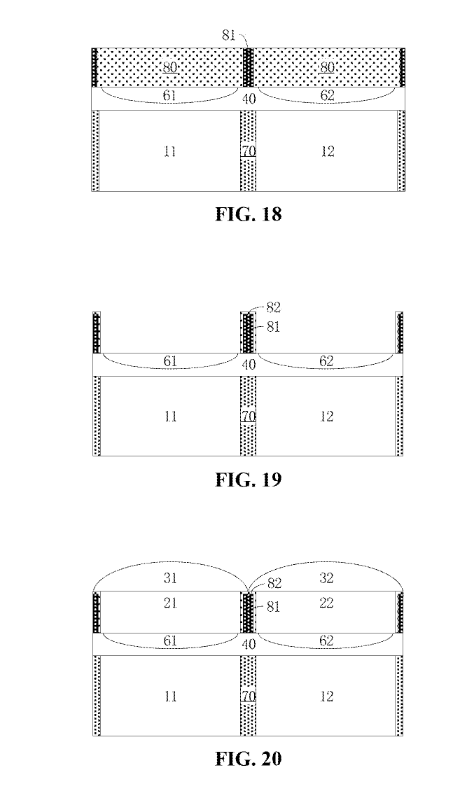

As shown in FIG. 16, a dielectric material layer 80 is formed above the anti-reflection layer 40 in which the converging lenses 61, 62 are formed. The portions of the dielectric material layer 80 that are located directly above the peripheral and/or surrounding regions of the photodiodes 11, 12 are removed so as to form a recess 83 for forming a body portion 81 of the optical isolation structure, as shown in FIG. 17. Filling the recess 83 with an opaque material (e.g., metal), such that the body portion 81 of the optical isolation structure is formed, as shown in FIG. 18. The dielectric material layer 80 is then removed, for example, by a dry etching process and/or a wet etching process, and then a cover portion 82 of a dielectric material is formed on the surface of the body portion 81 as shown in FIG. 19. It will be appreciated that the cover portion 82 may be formed by removing the dielectric material layer 80, that is, a portion of the dielectric material layer 80 that does not cover the body portion 81 is removed and a portion that covers the body portion 81 is retained, thereby the cover portion 82 is formed.

Finally, as shown in FIG. 20, color filters 21, 22 are formed above the anti-reflection layer 40 in which the converging lenses 61, 62 are formed, so that the color filters 21, 22 are filled between adjacent optical isolation structures. Then, microlenses 31, 32 are formed above the color filters 21, 22.

In the embodiment schematically illustrated in FIGS. 3 through 11 of the present disclosure, the step of forming the converging lenses 51, 52 in the layer that the color filters 21, 22 are located is after the step of forming the optical isolation structure between the pixel cells, and in the embodiment schematically illustrated in FIGS. 12 through 20 of the present disclosure, the step of forming the converging lenses 61, 62 in the layer that the anti-reflection layer 40 is located is before the step of forming the optical isolation structure between the pixel cells. It will appreciate that regardless of which converging lens is formed between the color filters 21, 22 and the photodiodes 11, 12, an optical isolation structure between the pixel cells may be formed either before or after the step of forming the converging lens.

While a structure of each image sensor has been shown in the accompanying drawings of the present disclosure in a form of fragmentary cross sections, an entire structure of each image sensor may be conceivable for those skilled in the art based on the description and accompanying drawings.

The term “A or B” used through the specification refers to “A and B” and “A or B” rather than meaning that A and B are exclusive, unless otherwise specified.

The terms “front,” “back,” “top,” “bottom,” “over,” “under” and the like, as used herein, if any, are used for descriptive purposes and not necessarily for describing permanent relative positions. It should be understood that such terms are interchangeable under appropriate circumstances such that the embodiments of the disclosure described herein are, for example, capable of operation in other orientations than those illustrated or otherwise described herein.

The term “exemplary”, as used herein, means “serving as an example, instance, or illustration”, rather than as a “model” that would be exactly duplicated. Any implementation described herein as exemplary is not necessarily to be construed as preferred or advantageous over other implementations. Furthermore, there is no intention to be bound by any expressed or implied theory presented in the preceding technical field, background, summary or detailed description.

The term “substantially”, as used herein, is intended to encompass any slight variations due to design or manufacturing imperfections, device or component tolerances, environmental effects and/or other factors. The term “substantially” also allows for variation from a perfect or ideal case due to parasitic effects, noise, and other practical considerations that may be present in an actual implementation.

In addition, the foregoing description may refer to elements or nodes or features being “connected” or “coupled” together. As used herein, unless expressly stated otherwise, “connected” means that one element/node/feature is electrically, mechanically, logically or otherwise directly joined to (or directly communicates with) another element/node/feature. Likewise, unless expressly stated otherwise, “coupled” means that one element/node/feature may be mechanically, electrically, logically or otherwise joined to another element/node/feature in either a direct or indirect manner to permit interaction even though the two features may not be directly connected. That is, “coupled” is intended to encompass both direct and indirect joining of elements or other features, including connection with one or more intervening elements.

In addition, certain terminology, such as the terms “first”, “second” and the like, may also be used in the following description for the purpose of reference only, and thus are not intended to be limiting. For example, the terms “first”, “second” and other such numerical terms referring to structures or elements do not imply a sequence or order unless clearly indicated by the context.

Further, it should be noted that, the terms “comprise”, “include”, “have” and any other variants, as used herein, specify the presence of stated features, integers, steps, operations, elements, and/or components, but do not preclude the presence or addition of one or more other features, integers, steps, operations, elements, components, and/or groups thereof.

In this disclosure, the term “provide” is intended in a broad sense to encompass all ways of obtaining an object, thus the expression “providing an object” includes but is not limited to “purchasing”, “preparing/manufacturing”, “disposing/arranging”, “installing/assembling”, and/or “ordering” the object, or the like.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The description and drawings are, accordingly, to be regarded in an illustrative rather than in a restrictive sense.

Although some specific embodiments of the present disclosure have been described in detail with examples, it should be understood by a person skilled in the art that the above examples are only intended to be illustrative but not to limit the scope of the present disclosure. The embodiments disclosed herein can be combined arbitrarily with each other, without departing from the scope and spirit of the present disclosure. It should be understood by a person skilled in the art that the above embodiments can be modified without departing from the scope and spirit of the present disclosure. The scope of the present disclosure is defined by the attached claims.

What is claimed is:

1. An image sensor, comprising:
a photodiode;
a color filter located above the photodiode; and
a converging lens located between the photodiode and the color filter, wherein the converging lens is configured to converge light onto the photodiode.

2. The image sensor according to claim 1, further comprising an anti-reflection layer located between the photodiode and the color filter,
wherein the converging lens is located between the anti-reflection layer and the color filter.

3. The image sensor according to claim 1, wherein a lower surface of the converging lens is flat and an upper surface thereof is curved, and the upper surface is completely covered by the color filter.

4. The image sensor according to claim 3, wherein the upper surface is in direct contact with the color filter.

5. The image sensor according to claim 3, wherein the converging lens is formed in a common layer with the color filter.

6. The image sensor according to claim 5, wherein a material forming the converging lens has a refractive index greater than a refractive index of a material forming the color filter.

7. The image sensor according to claim 3, wherein the converging lens is formed by:
forming a lens material layer above the anti-reflection layer;
forming a first photoresist layer above the lens material layer;
forming the first photoresist layer into a first shape whose lower surface is flat and upper surface is curved; and
etching the lens material layer under the masking of the first photoresist layer that is formed into the first shape such that the lens material layer is formed as the converging lens.

8. The image sensor according to claim 7, wherein the first photoresist layer is formed into the first shape at least by means of a reflow process and/or a nano-imprint lithography.

9. The image sensor according to claim 2, wherein an upper surface of the converging lens is flat and a lower surface thereof is curved, and the lower surface is completely covered by the anti-reflection layer.

10. The image sensor according to claim 9, wherein the lower surface is in direct contact with the anti-reflection layer.

11. The image sensor according to claim 9, wherein the converging lens is formed in a common layer with the anti-reflection layer.

12. The image sensor according to claim 11, wherein a material forming the converging lens has a refractive index greater than a refractive index of a material forming the anti-reflection layer.

13. The image sensor according to claim 11, wherein the converging lens is formed by:
forming a second photoresist layer above the anti-reflection layer;
forming the second photoresist layer into a second shape whose upper surface is flat and lower surface is curved;
etching the anti-reflection layer under the masking of the second photoresist layer that is formed into the second shape such that a pit having the second shape is formed in the anti-reflection layer; and
filling a lens material into the pit to form the converging lens.

14. The image sensor according to claim 13, wherein the second photoresist layer is formed into the second shape at least by means of a nano-imprint lithography.

15. The image sensor according to claim 1 further comprising an optical isolation structure located around the color filter for optical isolation between pixel cells of the image sensor.
